(19) United States
(12) Patent Application Publication
(10) Pub. No.: US 2014/0181625 A1
(43) Pub. Date: Jun. 26, 2014

(54) READ CHANNEL DATA SIGNAL DETECTION WITH REDUCED-STATE TRELLIS

(71) Applicant: LSI CORPORATION, Milpitas, CA (US)

(72) Inventors: Weijun Tan, Longmont, CO (US); Xuebin Wu, San Jose, CA (US); Shaohua Yang, San Jose, CA (US)

(73) Assignee: LSI Corporation, Milpitas, CA (US)

(21) Appl. No.: 13/721,417

(22) Filed: Dec. 20, 2012

(51) Int. Cl. H03M 13/25

(52) U.S. Cl. CPC H03M 13/256
USPC 714/792

(57) ABSTRACT

An apparatus comprises read channel circuitry and signal processing circuitry associated with the read channel circuitry. The signal processing circuitry is configured to determine a first set of soft outputs, hard decisions and reliability indicators for a read channel data signal, to determine a second set of soft outputs, hard decisions and reliability indicators based at least in part on the first set of soft outputs, hard decisions and reliability indicators, and to perform an iterative decoding process to decode the read channel data signal based at least in part on the second set of soft outputs, hard decisions and reliability indicators. The first set of soft outputs, hard decisions and reliability indicators are used to determine a reduced-state trellis for determining the second set of soft outputs, hard decisions and reliability indicators.

### FIELD

The field relates to signal processing, and, more particularly, to processing of digital data signals.

### BACKGROUND

Disk-based storage devices such as hard disk drives (HDDs) are used to provide non-volatile data storage in a wide variety of different types of data processing systems. A typical HDD comprises a spindle which holds one or more flat circular storage disks, also referred to as platters. Each storage disk comprises a substrate made from a non-magnetic material, such as aluminum or glass, which is coated with one or more thin layers of magnetic material. In operation, data is read from and written to tracks of the storage disk via a read/write head that is moved precisely across the disk surface by a positioning arm as the disk spins at high speed.

### SUMMARY

In one embodiment, an apparatus comprises read channel circuitry and signal processing circuitry associated with the read channel circuitry. The signal processing circuitry is configured to determine a first set of soft outputs, hard decisions and reliability indicators for a read channel data signal, to determine a second set of soft outputs, hard decisions and reliability indicators based at least in part on the first set of soft outputs, hard decisions and reliability indicators, and to perform an iterative decoding process to decode the read channel data signal based at least in part on the second set of soft outputs, hard decisions and reliability indicators. The first set of soft outputs, hard decisions and reliability indicators are used to determine a reduced-state trellis for determining the second set of soft outputs, hard decisions and reliability indicators.

Other embodiments of the invention include, by way of example and without limitation, methods, storage devices, virtual storage systems, integrated circuits and computer-readable storage media having computer program code embodied therein.

### BRIEF DESCRIPTION OF THE DRAWINGS

FIG. 1 shows a disk-based storage device, according to an embodiment of the invention.

FIG. 2 is a detailed view of portions of the read channel circuitry of FIG. 1, according to an embodiment of the invention.

FIG. 3 is a detailed view of portions of the read channel circuitry of FIG. 1, according to an alternate embodiment of the invention.

FIG. 4 is a detailed view of a detector, according to an embodiment of the invention.

FIG. 5 is another detailed view of a detector, according to an embodiment of the invention.

FIG. 6 is a flow diagram illustrating a methodology of reduced state detection, according to an embodiment of the invention.

FIG. 7 shows a virtual storage system incorporating a plurality of disk-based storage devices of the type shown in FIG. 1, according to an embodiment of the invention.

### DETAILED DESCRIPTION

Embodiments of the invention will be illustrated herein in conjunction with exemplary disk-based storage devices, read channel circuitry and associated signal processing circuitry for processing read channel data signals. For example, embodiments of the invention include HDDs or other types of storage devices that exhibit enhanced signal processing by using information from a first detector in subsequent detector processing of either a received signal or one or more subsequent signals. It should be understood, however, that these and other embodiments of the invention are more generally applicable to any storage device in which improved signal processing is desired. Additional embodiments may be implemented using components other than those specifically shown and described in conjunction with the illustrative embodiments.

The following acronyms are utilized in this description:

ADC Analog-to-Digital Converter

DFIR Digital Finite Impulse Response

HDD Hard Disk Drive

LDPC Low-Density Parity-Check

LLR Log Likelihood Reliability

MAP Maximum a Posteriori Probability

NPFIR Noise Predictive Finite Impulse Response

NRZ Non Return to Zero

RAID Redundant Array of Independent Storage Devices

RPM Revolutions Per Minute

RS Reed Solomon

SOVA Soft-output Viterbi Algorithm

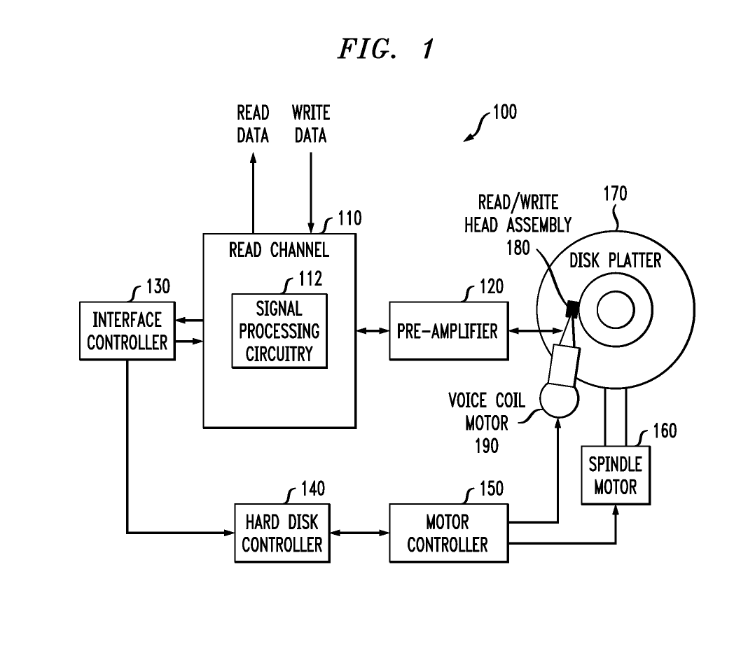

FIG. 1 shows a disk-based storage device 100 including read channel circuitry 110 having a signal processing circuitry 112 in accordance with various embodiments of the invention. Although shown in FIG. 1 as being incorporated within read channel circuitry 140, the signal processing circuitry 112 may also be implemented at least in part externally to the read channel circuitry 110. Storage device 100 may be, for example, a hard disk drive. Storage device 100 also includes a preamplifier 120, an interface controller 130, a hard disk controller 140, a motor controller 150, a spindle motor 160, a disk platter 170, read/write head assembly 180, and voice coil motor 190. Interface controller 130 controls addressing and time of data to and from disk platter 170. In some embodiments, disk platter 170 includes magnetic signals recorded in accordance with either a longitudinal or a perpendicular recording scheme.

Read/write head assembly 180 is positioned by voice coil motor 190 over a desired data track on disk platter 170. Motor controller 150 controls the voice coil motor 190. Motor controller 150 controls the voice coil motor 190 to position read/write head assembly 180 in relation to disk platter 170 and drives spindle motor 160 by moving read/write head assembly to the proper data track on disk platter 170 under direction of hard disk controller 140. Spindle motor 160 spins disk platter 170 at a determined spin rate (RPMs).

Once read/write head assembly 180 is positioned adjacent the proper data track, magnetic signals representing data on disk platter 170 are sensed by read/write head assembly 180 as disk platter 170 is rotated by spindle motor 160. The sensed magnetic signals are provided as an analog signal representative of the magnetic data on disk platter 170. This analog signal is transferred from read/write head assembly 180 to read channel circuitry 110 via preamplifier 120. Preamplifier 170 is operable to amplify the analog signals accessed from disk platter 170. In turn, read channel circuitry 110 decodes and digitizes the received analog signal to recreate the information originally written to disk platter 170. This data is provided as read data.

Various elements of the storage device 100 may be implemented at least in part within a processing device. A processing device includes a processor and a memory, and may be implemented at least in part within an associated host computer or server in which the storage device 100 is installed. Portions of the processing device may be viewed as comprising “control circuitry” as that term is broadly defined herein.

It is important to note that storage device 100 may include other elements in addition to or in place of those specifically shown, including one or more elements of a type commonly found in a conventional implementation of such a storage device. These and other conventional elements, being well understood by those skilled in the art, are not described in detail herein. It should also be understood that the particular arrangement of elements shown in FIG. 1 is presented by way of illustrative example only. Those skilled in the art will recognize that a wide variety of other storage device configurations may be used in implementing embodiments of the invention.

In order to improve the data readout performance of storage device 100, the read channel circuitry 110 incorporates signal processing circuitry 112.

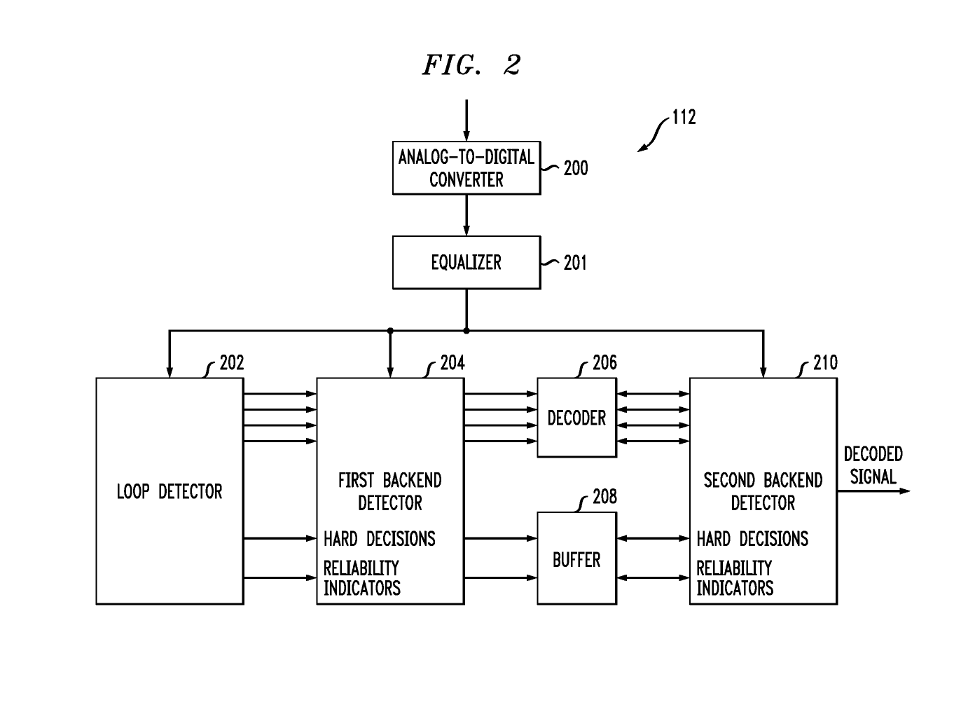

FIG. 2 shows an embodiment of the signal processing circuitry 112. An analog-to-digital (ADC) converter 200 receives an analog read channel signal from the read/write head assembly 180 and preamplifier 120. The ADC 200 converts the analog read channel signal into a digital data signal. The digital data signal is input to an equalizer 201, which determines an equalized digital data signal. The equalized digital data signal is input to a loop detector 202, a first backend detector 204 and a second backend detector 210. The equalizer 201 may comprise one or more digital finite impulse response (DFIR) filters.

The loop detector 202 receives the equalized digital data signal and determines a first set of soft outputs, hard decisions and reliability indicators. The loop detector 202 may comprise a number of noise predictive finite impulse response (NPFIR) filters and other circuitry operative to determine the set of soft outputs, hard decisions and reliability indicators using the equalized digital data signal. The equalized digital data signal may comprise a set of samples, referred to herein as y samples. The loop detector 202 may be a soft-output Viterbi algorithm (SOVA) detector, a maximum a posteriori probability (MAP) detector, or some combination of S OVA, MAP and other detector types.

The first backend detector 204 receives the first set of soft outputs, as well as hard decision information and reliability indicators from the loop detector 202. The reliability indicators, which are also referred to herein as reliability flags, are measures of the reliability of respective ones of the hard decisions. When the reliability flags indicate that the hard decisions are reliable, the first backend detector 204 can use the hard decisions and/or reliability flags when determining a second set of soft outputs, hard decisions and reliability indicators of the equalized digital data signal. Use of the hard decisions and reliability indicators reduces can be used to determine a reduced-state trellis for the first backend detector 204. The first backend detector 204 may comprise a number of NPFIR filters and other circuitry used to determine the second set of soft outputs, hard decisions and reliability indicators. The first backend detector 204, similar to the loop detector 202, may be a SOVA detector, MAP detector or some combination of SOYA, MAP and other detector types.

A decoder 206 has one or more inputs coupled to one or more outputs of the first backend detector 204. The decoder 206 is operative to perform an iterative decoding process to decode the equalized digital data signal using the second set of soft outputs and/or hard decisions received from the first backend detector 204. The decoder 206 may be a low-density parity-check (LDPC) decoder, Reed Solomon (RS) decoder, or some combination of LDPC, RS and other decoder types. A buffer 208 has one or more inputs coupled to one or more outputs of the first backend detector 204, and is operative to store the hard decision information and reliability indicators determined by the first backend detector 204.

The decoder 206 has one or more outputs coupled to one or more inputs of a second backend detector 210. The second backend detector 210 is operative to determine a third set of soft outputs, hard decisions and reliability indicators based at least in part on information received from the decoder 206. The hard decisions and reliability indicators determined by the second backend detector 210 are stored in the buffer 208. The second backend detector 210 is configured to output the decoded signal. The third set of soft outputs, hard decisions and reliability indicators may be used to determine a reduced-state trellis in the loop detector 202 for a subsequent equalized digital data signal received from the ADC 200 or for additional processing on the received equalized digital data signal.

FIG. 3 shows another embodiment of portions of the signal processing circuitry 112. A backend detector 304 receives an equalized digital data signal, and is configured to determine a set of soft outputs, hard decisions and reliability indicators of the equalized digital data signal. The backend detector 304 may comprise a set of NPFIR filters and other circuitry used to determine the set of soft outputs, hard decisions and reliability indicators. A buffer 308 has one or more inputs coupled to one or more outputs of the backend detector 304. The buffer 308 can store the set of hard decisions and reliability indicators. The buffer 308 can pass the set of soft outputs to an interleaver/de-interleaver 309. The interleaver/de-interleaver 309 has one or more outputs coupled to a decoder 310. The decoder 310 is configured to perform an iterative decoding process on the equalized digital data signal based at least in part on the set of soft outputs received from the interleaver/de-interleaver 309.

The decoder 310 passes the decoded signal to the interleaver/de-interleaver 309, which in turn passes the decoded signal to the buffer 308 and backend detector 304. The backend detector 304 can use the set of hard decisions and reliability indicators stored in the buffer 308 to determine a reduced-state trellis for determining a new set of soft outputs, hard decisions and reliability indicators for the equalized digital data signal. The backend detector 304, interleaver/de-interleaver 309 and decoder 310 may faun a processing loop which performs a number of iterations on the equalized digital data signal. Thus, the backend detector 304 can use the set of hard decisions and reliability indicators stored in the buffer 308 to determine a new set of soft outputs, hard decisions and reliability indicators for the decoded signal. Alternatively or additionally, the backend detector 304 can use the set of hard decisions and reliability indicators to determine a reduced-state trellis when determining a new set of soft outputs, hard decisions and reliability indicators for a new equalized digital data signal. In addition, hard decisions or the decoded digital data signal determined by the decoder 310 may alternatively be used to determine a reduced-state trellis for future detector processing.

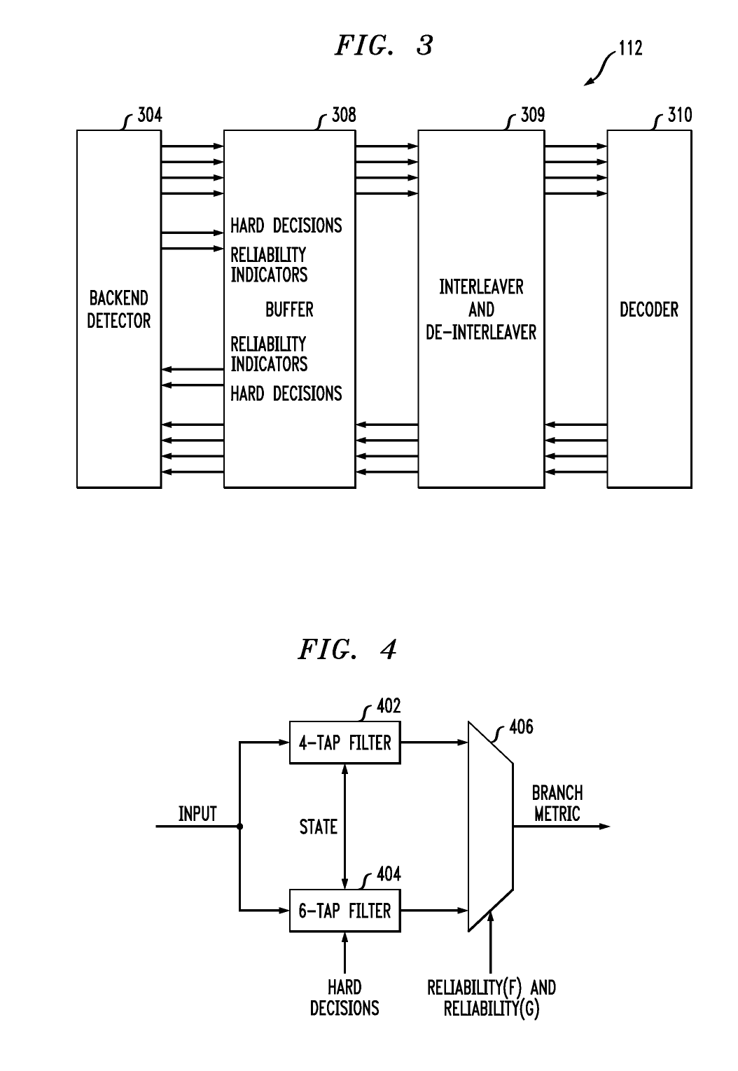

FIG. 4 shows an embodiment of portions of a reduced-state detector, according to embodiments of the invention. A detector includes a 4-tap filter 402, a 6-tap filter 404 and a multiplexer 406. The detector receives an input signal, which is passed to both the 4-tap filter 402 and the 6-tap filter 404. The 6-tap filter 404, in addition to receiving the input signal, receives a set of hard decisions. The set of hard decisions may be received from another detector, a buffer, or decoder as described above with respect to FIGS. 2 and 3. Each of the 4-tap filter 402 and the 6-tap filter 404 determines a set of edgeMeans and biases. Ideally, the mean of the filter output is given by the tap coefficient convolved with the equalization target, also referred to as the effective target for the filter, and then convolved with a corresponding non return to zero (NRZ) sequence resulting in what is referred to herein as an edgeIdeal. Due to non-linearity and mis-equalization, the mean of the filter output has some bias from the edgeIdeal, referred to herein as edgeBias. The edgeMean is the sum of the edgeIdeal and edgeBias.

The 4-tap filter 402 determines 32 biases based on a 5-bit pattern a[bcde], where the detector is configured as a 16-state detector with 4 bit states [bcde]. The 16-state detector has 8 unique NPFIR filters with data dependency length 4 and a bias dependency length 5. The 5-bit pattern a[bcde] means a transition from state [bcde] to [abed]. The bit e is reduced such that 0[1010] and 0[1011] share the same configuration. The 4-tap filter 402 is also subject to polar collapse such that 0[1010] and 1[0101] share the same configuration. The configurations may be NPFIR configurations where the detector comprises a number of NPFIR filters. In other embodiments, the 4-tap filter 402 may use extra taps to increase the 4-tap filter to a 6-tap filter, and thus calibrate NPFIR filters corresponding to a bit pattern a[bcde]xx.

The 6-tap filter 404 determines 128 biases based on a 7-bit pattern a[bcde]FG, where the detector is configured as a 64-state detector. To reduce the complexity of the 64-state detector, the F and G bits are used as feedback to determine a reduced-state trellis thus reduced the 64-state detector to a 16-state detector with 4 bit states [bcde]. The tap data and bias data dependency of the 6-tap filter, 404 is abcd(eFG). When bits F and G are indicated as reliable, the edgeMean is calculated from abcde FG. Again, the 7-bit pattern a[bcde]FG means a transition from state [bcde] to [abcd]. The bit e is reduced such that 0[1010]10 and 0[1011]10 share the same configuration. The 6-tap filter 404 is also subject to polar collapse such that 0[1010]10 and 1[0101]10 share the same configuration. The configurations may be NPFIR configurations where the detector comprises a number of NPFIR filters. In other embodiments, the 6-tap filter 404 can remove data dependency on bit G and add dependence on bit e. A particular NPFIR configuration can thus be based on hard decision EF.

In embodiments of the invention, the complexity of a 64-state detector can thus be reduced to a 16-state detector with only 8 6-tap NPFIR filters, rather than requiring 4 4-tap NPFIR filters and 32 6-tap NPFIR filters.

In some embodiments, the determination of reliability indicators is based on bit-wise total log likelihood reliability (LLR). For example, the detector may output two hard decision bits AB and three soft outputs LLR(!AB), LLR(A!B) and LLR(!A!B) for each symbol in an equalized digital data signal. The bit-wise total LLR for hard decision bit A may be determined according to the following equation

LLR(A)=LLR(A!B)−max(LLR(!AB),LLR(!A!B)). (1)

The bit-wise total LLR for hard decision bit B may be determined according to the following equation

LLR(B)=LLR(!AB)−max(LLR(A!B),LLR(!A!B)). (2)

In some embodiments, a hard decision bit is determined to be reliable if the bit-wise total LLR for the hard decision bit is greater than 4. One skilled in the art, however, will readily appreciate that various other thresholds may be used to determine whether a given hard decision bit is reliable as desired.

When bits F and G are not indicated as reliable, the edgeMean is calculated from abcde. The 4-tap filter 402, which is used when bits F and G are not reliable, calculates 32 biases and 32 edgeMeans from the edge label abcde. The 6-tap filter, which is used when bits F and G are reliable, calculates 128 biases and 128 edgeMeans from edge label abcdeFG. Each filter can transfer the set of biases and edgeMeans to another filter or other component. The old edgeMeans mean(abcde) and delta(abcdeFG) can be used for shadow registers and filter transfer. delta(abcdeFG) can be calculated by subtracting edgeMean(abcde) from edgeMean(acbdeFG). delta(abcdeFG) is saved instead of the edgeMeans to save the number of registers required. EdgeMean(abcdeFG) and edgeMean(abcde) are normally close to one another, and thus delta(abcdeFG) is small and can be saved in a fewer number of registers.

In some embodiments, taps 4 and 5 of the 6-tap filter 404 may have the same precision configuration as tap 3. While shown in FIG. 4 as comprising separate 4-tap and 6-tap filters, a reduced-state detector for use in embodiments of the invention may instead use only 6-tap filters. Such a reduced-state detector may be configured with 4-tap filters by setting taps 4 and 5 to 0.

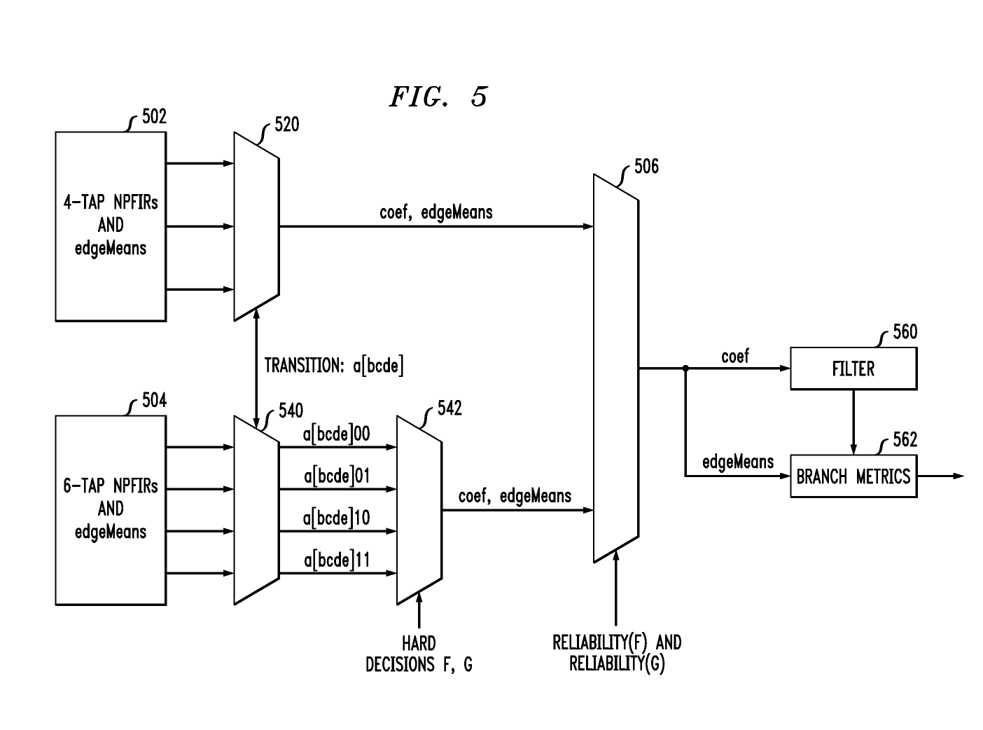

FIG. 5 illustrates an example of filter selection. 4-tap NPFIR filters and edgeMeans calculations are performed in element 502. The results of these calculations are input to a multiplexer 520. Depending on the transition a[bcde], the multiplexer 520 will choose a particular set 522 of the tap coefficients and edgeMeans calculated in element 502, which are input to multiplexer 506.

In element 504, 6-tap NPFIR filters and edgeMeans calculations are performed. The results of these calculations are input to a multiplexer 540. Again depending on the transition a[bcde], the multiplexer 540 outputs a set of results for the transition a[bcde] for each of the four possible combinations of hard decision bits FG, represented as 541-1, 541-2, 541-3 and 541-4 in FIG. 5. The set of results 541-1 through 541-4 are input to a multiplexer 542. Based on the hard decision bits FG received from another detector or from a previous iteration of processing in a given detector, the multiplexer 542 selects a given one of the results 541-1 through 541-4 to determine a set of tap coefficients and edgeMeans which are input to multiplexer 506.

Multiplexer 506 receives a set of tap coefficients and edgeMeans from multiplexer 520 and multiplexer 542. Based on the reliability indicators for hard decision bits F and G, represented as reliability(F) and reliability(G) in FIG. 5, a given one of the sets of tap coefficients and edgeMeans is output by the multiplexer 506. If reliability(F) and reliability(G) indicate that both hard decision bits F and G are reliable, the set of tap coefficients and edgeMeans received from multiplexer 542 are input to the filter 560 and branch metrics module 562, respectively. When reliability(F) or reliability(G) indicates that at least one of the hard decision bits F and G are not reliable, the set of tap coefficients and edgeMeans received from multiplexer 520 are input to the filter 560 and branch metrics module 562, respectively. The detector will determine a set of soft outputs, hard decisions and reliability indicators on an equalized digital data signal using the set of tap coefficients and edgeMeans received from the multiplexer 506.

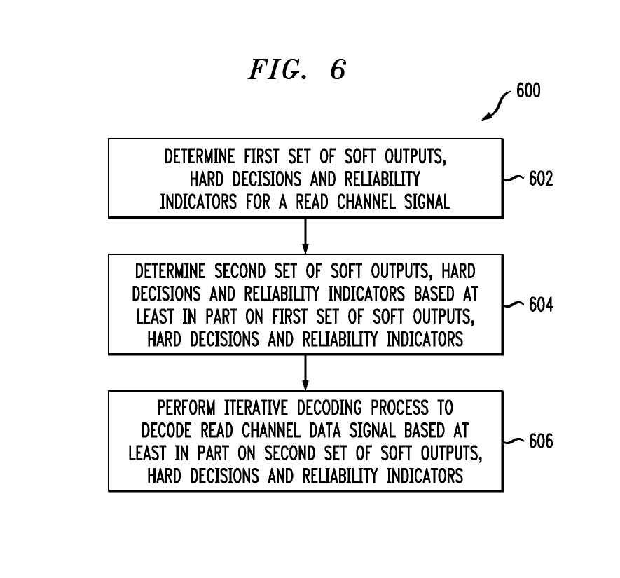

FIG. 6 illustrates a methodology 600 of reduced-state detection. In step 602, a first set of soft outputs, hard decisions and reliability indicators for a read channel data signal are determined. A second set of soft outputs, hard decisions and reliability indicators are determined in step 604 based at least in part on the first set of soft outputs, hard decisions and reliability indicators. The first set of soft outputs, hard decisions and reliability indicators are used to determine a reduced state trellis for determining the second set of soft outputs, hard decisions and reliability indicators. An iterative decoding process is performed in step 606 to decode the read channel data signal based at least in part on the second set of soft outputs, hard decisions and reliability indicators.

As mentioned previously, the storage device configuration can be varied in other embodiments of the invention. For example, the storage device may comprise a hybrid HDD which includes a flash memory in addition to one or more storage disks.

In addition, storage device 100 may be coupled to or incorporated within a host processing device, which may be a computer, server, communication device, etc.

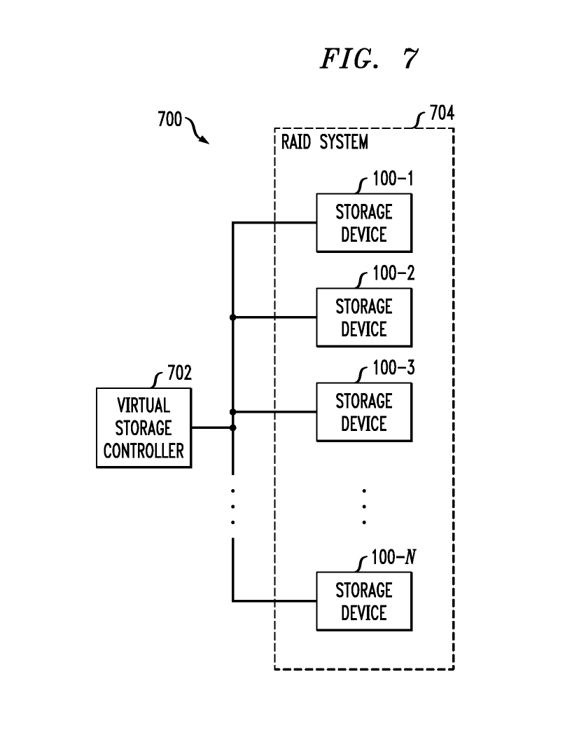

Multiple storage devices 100-1 through 100-N possibly of various different types may be incorporated into a virtual storage system 700 as illustrated in FIG. 7. The virtual storage system 700, also referred to as a storage virtualization system, illustratively comprises a virtual storage controller 702 coupled to a RAID system 704, where RAID denotes Redundant Array of Independent storage Devices. The RAID system more specifically comprises N distinct storage devices denoted 100-1, 100-2, . . . 100-N, one or more of which may be HDDs and one or more of which may be solid state drives. Furthermore, one or more of the HDDs of the RAID system are assumed to be configured to include read channel circuitry and associated signal processing circuitry as disclosed herein. These and other virtual storage systems comprising HDDs or other storage devices are considered embodiments of the invention.

Embodiments of the invention may also be implemented in the form of integrated circuits. In a given such integrated circuit implementation, identical die are typically formed in a repeated pattern on a surface of a semiconductor wafer. Each die includes, for example, at least a portion of signal processing circuitry 112 as described herein, and may further include other structures or circuits. The individual die are cut or diced from the wafer, then packaged as an integrated circuit. One skilled in the art would know how to dice wafers and package die to produce integrated circuits. Integrated circuits so manufactured are considered embodiments of the invention.

It should again be emphasized that the above-described embodiments of the invention are intended to be illustrative only. For example, other embodiments can use different types and arrangements of storage disks, read/write heads, read channel circuitry, signal processing circuitry, decoders, filters, detectors, and other storage device elements for implementing the described signal processing functionality. Also, the particular manner in which certain steps are performed in the signal processing may vary. Further, although embodiments of the invention have been described with respect to storage disks such as HDDs, embodiments of the invention may be implemented various other devices including optical data-storage applications and wireless communications. These and numerous other alternative embodiments within the scope of the following claims will be apparent to those skilled in the art.

What is claimed is:

1. An apparatus, comprising:
read-channel circuitry; and
signal processing circuitry associated with the read channel circuitry, the signal processing circuitry being configured to:
determine a first set of soft outputs, hard decisions and reliability indicators for a read channel data signal;
determine a second set of soft outputs, hard decisions and reliability indicators based at least in part on the first set of soft outputs, hard decisions and reliability indicators; and
perform an iterative decoding process to decode the read channel data signal based at least in part on the second set of soft outputs, hard decisions and reliability indicators;
wherein the first set of soft outputs, hard decisions and reliability indicators are used to determine a reduced-state trellis for determining the second set of soft outputs, hard decisions and reliability indicators.

2. The apparatus of claim 1, wherein the signal processing circuitry is further configured to determine a third set of soft outputs, hard decisions and reliability indicators, the third set of soft outputs, hard decisions and reliability indicators, and wherein for a subsequent read channel data signal the third set of soft outputs, hard decisions and reliability indicators are used to determine a reduced-state trellis for determining the first set of soft outputs, hard decisions and reliability indicators of the subsequent read channel data signal.

3. The apparatus of claim 2, wherein the signal processing circuitry comprises:
a loop detector configured to determine the first set of soft outputs, hard decisions and reliability indicators;
a first backend detector configured to determine the second set of soft outputs, hard decisions and reliability indicators; and
a second backend detector configured to determine the third set of soft outputs, hard decisions and reliability indicators.

4. The apparatus of claim 3, wherein at least one of the loop detector, first backend detector and second backend detector comprises at least one of: a soft output Viterbi algorithm detector and a maximum a posteriori probability detector.

5. The apparatus of claim 1, wherein the signal processing circuitry comprises a first detector comprising a set of noise predictive finite impulse response filters configured to determine the second set of soft outputs, hard decisions and reliability indicators.

6. The apparatus of claim 5, wherein a number of taps of each of the noise predictive finite impulse response filters is configurable in a first state when the first set of reliability indicators is above a specified threshold and is configurable in a second state when the first set of reliability indicators is at or below the specified threshold.

7. The apparatus of claim 6, wherein in the first state each of the noise predictive finite impulse response filters is configured to determine a set of biases using the first set of hard decisions.

8. The apparatus of claim 6 wherein in the second state each of the noise predictive finite impulse response filters is configured to determine a set of biases without using the first set of hard decisions.

9. The apparatus of claim 1, wherein the signal processing circuitry comprises a first detector configured to determine the first set of soft outputs, hard decisions and reliability indicators, the first detector comprising a set of filters configurable with a first number of taps using the first set of hard decisions if the first set of reliability indicators is above a specified threshold and wherein the set of filters are configurable with a second number of taps when the first set of reliability indicators is at or below the specified threshold.

10. The apparatus of claim 9, wherein the first number is 6 and the second number is 4.

11. The apparatus of claim 10, wherein the set of filters are configurable with the second number of taps by setting one or more tap coefficients to 0.

12. The apparatus of claim 9, wherein each of the filters is a unique multi-tap noise predictive finite impulse response filter with a respective set of tap coefficients.

13. The apparatus of claim 1, wherein the first set of reliability indicators is determined based on a bit-wise total log likelihood reliability of the read channel data signal.

14. The apparatus of claim 1, further comprising a disk controller coupled to the read channel circuitry.

15. The apparatus of claim 1 wherein the read channel circuitry and associated signal processing circuitry are fabricated in at least one integrated circuit.

16. A storage device comprising the apparatus of claim 1.

17. A virtual storage system comprising the storage device of claim 16.

18. A method comprising the steps of:
determining a first set of soft outputs, hard decisions and reliability indicators for a read channel data signal;
determining a second set of soft outputs, hard decisions and reliability indicators based at least in part on the first set of soft outputs, hard decisions and reliability indicators; and
performing an iterative decoding process to decode the read channel data signal based at least in part on the second set of soft outputs, hard decisions and reliability indicators;
wherein the first set of soft outputs, hard decisions and reliability indicators are used to determine a reduced-state trellis for determining the second set of soft outputs, hard decisions and reliability indicators.

19. The method of claim 18, further comprising the step of determining a third set of soft outputs, hard decisions and reliability indicators, the third set of soft outputs, hard decisions and reliability indicators being used to reduce a trellis state for determining the first set of soft outputs, hard decisions and reliability indicators of a subsequent read channel data signal.

20. A storage device comprising:
at least one storage medium;
a read head configured to read data from the storage medium; and
control circuitry coupled to the read head and configured to process data received from the read head;
the control circuitry comprising:
read channel circuitry; and
signal processing circuitry associated with the read channel circuitry, the signal processing circuitry being configured to:
determine a first set of soft outputs, hard decisions and reliability indicators for a read channel data signal;
determine a second set of soft outputs, hard decisions and reliability indicators based at least in part on the first set of soft outputs, hard decisions and reliability indicators; and
perform an iterative decoding process to decode the read channel data signal based at least in part on the second set of soft outputs, hard decisions and reliability indicators;
wherein the first set of soft outputs, hard decisions and reliability indicators are used to determine a reduced-state trellis for determining the second set of soft outputs, hard decisions and reliability indicators.
